(19) United States
(12) Patent Application Publication
(10) Pub. No.: US 2004/0104463 A1
(43) Pub. Date: Jun. 3, 2004

(54) Crack resistant interconnect module

(76) Inventors: Robin E. Gorrell, Eau Claire, WI (US); Mark F. Sylvester, Landenberg, PA (US); Donald R. Banks, Eau Claire, WI (US); Michael D. Holcomb, Cadott, WI (US); William V. Ballard, Altoona, WI (US); Kouichi Hirosawa, Kawasaki (JP); Sadanobu Satou, Kawasaki (JP); Teruhiko Kimura, Kawasaki (JP)

Correspondence Address: 3M INNOVATIVE PROPERTIES COMPANY, PO BOX 33427, ST. PAUL, MN, 55133-3427, US

(21) Appl. No.: 10/668,881

(22) Filed: Sep. 23, 2003

Related U.S. Application Data
(60) Provisional application No. 60/414,461, filed on Sep. 27, 2002.

(51) Int. Cl. H01L 23/02

(52) U.S. Cl. 257/686

(57) ABSTRACT

A laminated flip-chip interconnect package comprising a substrate having a chip attach surface and a board attach surface that define contact pads for attachment to corresponding pads on the chip and board wherein the substrate board surface comprises at least one solid plane covering the chip attach surface region near at least one chip corner. In one embodiment, the solid plane comprises a dielectric material, optionally covered with a soldermask or coverlay material. In an alternate embodiment, the solid plane comprises a metal, optionally covered with a soldermask or coverlay material.

### RELATED APPLICATION

This application claims priority to provisional U.S. patent application 60/414461, filed Sep. 27, 2002, which is hereby incorporated by reference.

### TECHNICAL FIELD

The invention relates to interconnect modules for use with integrated circuit chips.

### BACKGROUND

Multi-layered interconnect modules are widely used in the semiconductor industry to mechanically support integrated circuit chips and electrically attach the chips to printed wiring boards. Interconnect modules can be configured to support a single chip or multiple chips, and are typically identified by the designation SCM (single chip module) or MCM (multi-chip module).

An interconnect module provides interconnections that serve to electrically couple an integrated circuit chip to signal lines, power lines, and other components carried by a printed wiring board. In particular, the interconnect module provides interconnections that redistribute the densely packed inputs and outputs (I/Os) of the chip to corresponding I/Os on the printed wiring board. In addition to electrical interconnection, an interconnect module typically serves to mechanically couple a chip to a printed wiring board, and may perform other functions such as heat dissipation and environmental protection.

After bonding together a low coefficient of thermal expansion (CTE) (˜2.6 ppm/° C. for silicon) integrated circuit (IC) to a relatively thin (<0.75 mm), and therefore flexible, package substrate with a relatively high CTE (>15 ppm/° C.) at elevated temperature, significant intrinsic tensile stresses and strains develop in the package as the substrate cools to a lower temperature. Some of these may arise directly from the bonding of the two components. In such a package, the stresses or strains in a particular region may rise to a level that induces cracks in the substrate dielectric and/or conductor materials. This may occur after a single low temperature exposure through fracture or after repeated exposures via fatigue.

In order to improve this situation, an interconnect module, in accordance with the invention, incorporates a plurality of alternating dielectric and metal layers that are laminated together to form a unitary structure. The laminated interconnect structure may incorporate a number of vias and patterned signal layers that provide conductive interconnection paths between the chip, the printed wiring board, and various layers within the interconnect module. The interconnect module includes chip attach and board attach surfaces that define contact pads for attachment to corresponding pads on the chip and board, respectively, via solder balls. The various layers are selected to present coefficients of thermal expansion (CTE) that promote reliable interconnections with the chip and the PWB.

### SUMMARY

The invention provides a flip-chip integrated circuit (IC) package that has a reduced or non-existent tendency to develop these cracks. Flip-chip packages of the invention comprise at least one solid plane on the Ball Grid Array (BGA) side of the package substrate encompassing regions around at least one of the four corners of the integrated chip (IC, also called the “die”) or “die shadow”. The size and shape of the regions covered by the plane varies based on other design features of the package. These planes may be used as power or ground connections by defining BGA pads on the planes using soldermask. An important aspect of the invention is that it provides an area without geometric discontinuity on the BGA side surface in the region near the die corners.

In at least one embodiment of the present invention, laminated flip-chip interconnect packages comprise a substrate having a chip attach surface and a board attach surface that define contact pads for attachment to corresponding pads on the chip and board wherein the substrate board surface comprises at least one solid plane covering the chip attach surface region near the chip corners. The solid plane comprises a dielectric material, optionally covered with a soldermask or coverlay material.

In at least one embodiment of the present invention, the flip-chip package comprises at least one solid plane wherein the region near the chip corners consist of a solid plane of metal, optionally covered with a soldermask or coverlay material.

In another embodiment of the present invention, the solid plane comprises a solid plane of metal covered with a soldermask material, said soldermask having openings that define BGA pads.

Other features of flip-chip IC package of the invention may vary; however, it is desirable that the package remain relatively thin and flexible.

The following terms have these meanings as used herein:

1. The term “conductive” as used herein means electrically conductive.

2. The term “geometric discontinuity” means a feature such as a contact pad or opening that interrupts a continuous area of material.

3. The term “interconnect substrate” as used herein is equivalent to the terms “package substrate”, “flexible package substrate”, “rigid package substrate”, and the like.

4. The term “solid plane” means an area of a single material having no geometric discontinuities.

### BRIEF DESCRIPTION OF DRAWINGS

FIG. 1 is a schematic cross-section of a typical assembled interconnect module.

FIGS. 2a and 2b are schematics of regions of crack formation on an interconnect module; 2b is an exploded view of the regions shown in 2a .

FIG. 3 is a schematic cross-sectional representation of a seven metal layer interconnect substrate.

FIG. 4 is a schematic cross-sectional representation of a seven metal layer interconnect substrate.

FIGS. 5a and 5b are schematics cross-sections illustrating deformation behavior of an interconnect module upon cooling.

FIG. 6 is a graph showing fracture toughness of MICROLAM dielectric material as a function of temperature.

FIG. 7 is a graph showing fatigue behavior of MICROLAM dielectric material used in the interconnect substrate.

FIG. 8 is a detailed finite element model geometry of an interconnect substrate.

FIG. 9 is a detailed finite element model geometry of the maximum principal strain in a BGA-side dielectric layer of an interconnect substrate around a bond pad.

FIG. 10 is a graph showing stress concentration profiles around a BGA bond pad.

FIGS. 11a to 11c are finite element models of the effect of the size of a die-stiffener gap on the relative desirable size and shape of the solid die corner plane.

FIG. 12 illustrates a die corner plane design rule to determine the desirable size and location of the solid die corner plane relative to the corner of the die.

FIGS. 13a and 13b illustrate solid planes at die corners in the form of unpatterned areas of a chip attach surface.

### DETAILED DESCRIPTION

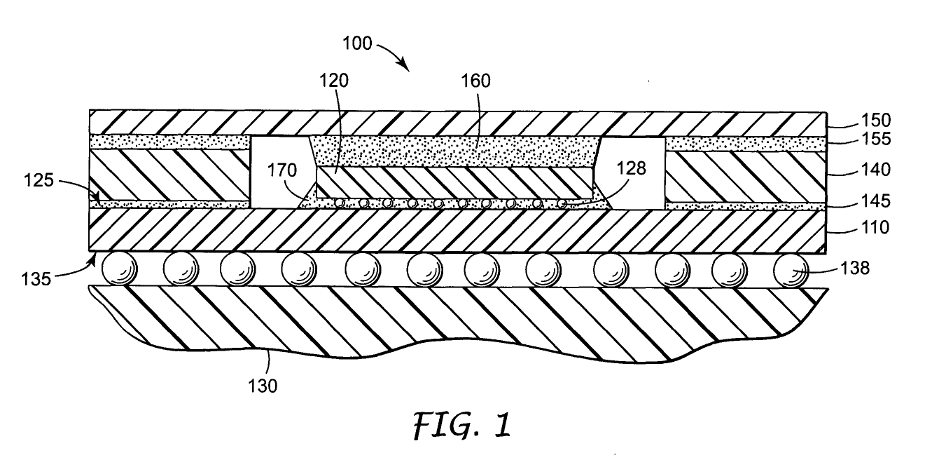

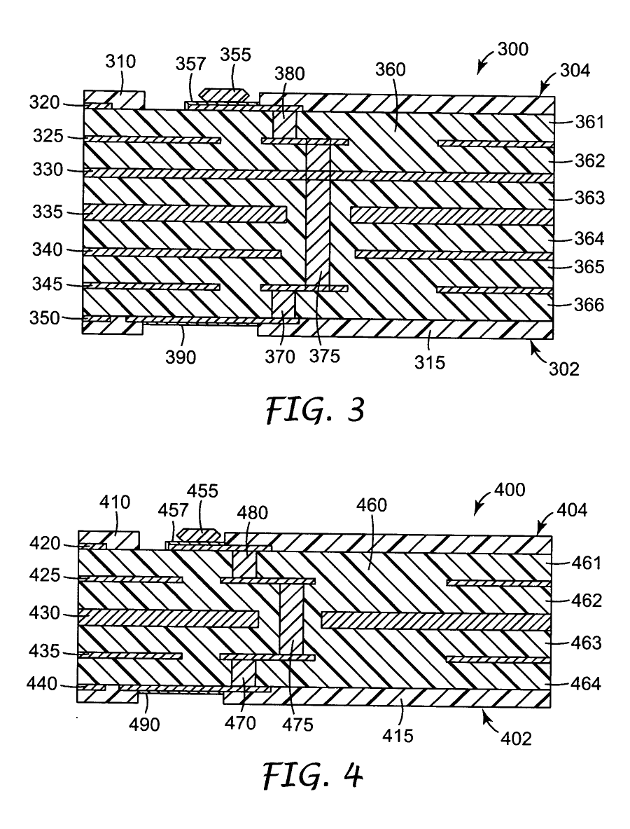

An interconnect module 100, as shown in FIG. 1, may incorporate a series of alternating dielectric and metal layers that are laminated together to form a unitary interconnect substrate 110 (depicted as a single material). The laminated interconnect substrate 110 may incorporate a number of vias and patterned signal layers (not shown) that provide conductive interconnection paths between the chip 120, the printed wiring board 130, and various layers within the interconnect module. FIGS. 3 and 4 are detailed schematics of laminated interconnect substrates. The interconnect module includes a chip attach surface 125 and a board attach surface 135 that define contact pads for attachment to corresponding pads on the chip and board, respectively, via solder balls 128, 138 to provide electrical and mechanical connections between the chip and the interconnect substrate and the interconnect substrate and the printed wiring board (PWB). The various layers are selected to have coefficients of thermal expansion (CTE) that promote reliable interconnections with the chip and the PWB. The interconnect module may also include a stiffening member 140 that is bonded by an adhesive 145 to the interconnect substrate 110 on the chip attach surface 125 such that the chip is centered within the stiffening member. An underfill adhesive 170 may be placed between the chip attach surface 125 of the interconnect substrate 110 and the bottom side of the chip, thus encapsulating the chip attach solder balls 128. Finally, a lid assembly 150 may be bonded by an additional adhesive layer 155 to the topside of the stiffening member. It is possible that a thermally conductive adhesive or elastomer 160 material will be interposed between the top surface of the chip 120 and the lid assembly 150 to assist in dissipating heat generated by the chip during operation.

After bonding together a low coefficient of thermal expansion (CTE) (˜2.6 ppm/° C. for silicon) IC chip 120 to a relatively thin (<0.75 mm), and therefore flexible, package substrate 110 with a relatively high CTE (>15 ppm/° C.) at elevated temperature, significant intrinsic tensile stresses and strains develop in the package as the substrate cools to a lower temperature. Some of these may arise directly from the bonding of the two components together. Others may arise from constraining or partially constraining the package substrate from flexing in response to these direct intrinsic stresses or strains. Such constraints can occur when using a stiffening member 140 in the package such as a ring or a lid assembly 150.

In such a package substrate, the stresses or strains in a particular region may rise to level that induces cracks in the dielectric and/or conductor materials making up the substrate. This may occur after either a single low temperature exposure through fracture or after repeated exposures through a fatigue process.

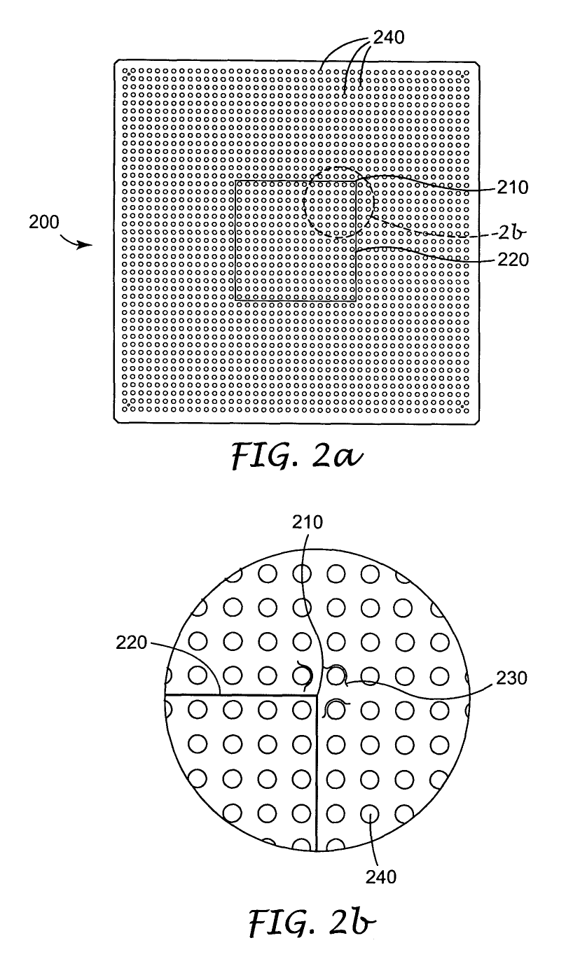

Cracks have been found to form in two regions in interconnect module parts on thermal cycling between +125° C. and −40° C. or −55° C. FIGS. 2a and 2b show a map of the locations where cracks form on a BGA interconnect module 200. FIG. 2b is an expanded view of the gray circular region in FIG. 2a. The figure shows an array of solder ball pads 240 on the BGA side of the substrate for a given interconnect module. The first region is just outside of the die corners 210 where the edge of the die 220 is shown by the dark line, and in some extreme cases also running down along the edge of the die. The presence of a crack 230 is indicated at solder ball pads 240 in close proximity to the corner of the die.

Experimental evidence indicates cracks form by a classic fatigue process. The cracks are found to initiate from the edge of a metal feature, most commonly a BGA pad (390 in FIG. 3 and 490 in FIG. 4) on BGA surface of the interconnect module (302 in FIG. 3 and 402 in FIG. 4) adjacent to metal layer (350 in FIG. 3 or metal layer 440 in FIG. 4). They can propagate into adjacent metal and dielectric layers (345, 365, and 366 in FIG. 3 and 435, 463, and 464 in FIG. 4). For example, if a growing dielectric crack encounters a signal trace on a metal layer prior to a plane layer, the trace can in turn crack, forming an electrical open. Cracks will often propagate until they reach a solid plane such as the metal power plane (340) in FIG. 3 or the metal “core” plane in FIG. 4 (430). These planes act as “crack stoppers” because they have no geometric discontinuities that allow a crack to easily propagate. A dielectric material can be used to form a crack-stopping plane, but metals such as copper are often preferred because of the intrinsically higher toughness of copper compared to some dielectric materials.

FIG. 3 is a schematic representation of a portion of one possible interconnect substrate in combination with which the invention herein described may be used. FIG. 3 shows a 7-layer interconnect substrate 300 made by laminating a alternating series of metal layers (320 (pad and/or plane), 325 (signal), 330(power or ground), 335 (core), 340 (power or ground), 345 (signal), and 350 (pad and/or plane)) and dielectric layers (361, 362, 363, 364, 365 and 366). The metal and dielectric layers shown in FIG. 3 are disposed symmetrically about core metal layer 335. That is, each dielectric or metal layer formed on one side of core layer 335 has a corresponding layer of the same material formed on the opposite side of the core layer.

As further shown in FIG. 3, a first via 380 extends through dielectric layer 361 from metal layer 320 and terminates at metal layer 325. A second via 375 begins at metal layer 325 and extends through dielectric layers 362, 363, 364 and 365, and terminates at metal layer 345. A third via 370 extends through dielectric layer 366 from metal layer 345 and terminates at metal layer 350. Each via 370, 375, 380 is plated with conductive material using any of the deposition techniques that are well known in the microelectronic fabrication art. Alternatively, each via 370, 375, 380 is filled with an electrically conductive material to define a conductive path. One skilled in the art will recognize that any combination of vias can be used to provide electrical connections between bond pads 357 on the die attach surface 304 and bond pads 390 on the BGA attach surface 302, including blind vias, buried vias and through vias.

Solder masks 310, 315 can be applied to chip attach surface 304 and BGA attach surface 302. Solder masks are typically made of filled epoxy material. Each solder mask 310, 315 exposes a contact or bond pad adjacent to each via 370, 375, 380. For example, solder mask 310 exposes contact pads 357, whereas solder mask 315 exposes contact pads 390. Solder balls 355 associated with the chip can be aligned over contact pads 357, heated, and reflowed to form electrical and mechanical bonds with the contact pads. Likewise, solder balls (not shown) associated with the board can be aligned over contact pads 390, heated, and reflowed to form electrical and mechanical bonds between the contact pads and the PWB.

The dielectric layers 361, 362, 363, 364, 365 and 366 may be formed from laminates of high-temperature organic dielectric substrate materials, such as polyimides and polyimide laminates, epoxy resins, liquid crystal polymers, organic materials, or dielectric materials comprised at least in part of polytetrafluoroethylene, with or without a filler. In one embodiment, dielectric layers 361, 362, 363, 364, 365 and 366 are made of an organic material such as polytetrafluoroethylene (PTFE), and more particularly, an expanded PTFE or “ePTFE” which is impregnated with cyanate ester and epoxy. The PTFE material may be, in particular, an expanded polytetrafluoroethylene matrix containing a mixed cyanate ester-epoxy adhesive and inorganic filler.

Metal layers 320, 325, 330, 335, 340, 345, and 350 may be formed from copper. Other suitable metals can also be used such as aluminum, gold, or silver. In this example, metal layers 320, 325, 330, 340, 345, and 350 may each have a thickness in the range of approximately 5 to 14 microns. In one example, the thickness of each metal layer 320, 325, 330, 340, 345, and 350 is approximately 12 microns. The core metal layer 335 may have a thickness in the range of approximately 5 to 50 microns. Dielectric layers 361, 362, 363, 364, 365 and 366 may each have a thickness in the range of approximately 20 to 70 microns. In one example, the thickness of each dielectric 361, 362, 363, 364, 365 and 366 layer is approximately 36 microns.

The various layers of interconnect substrate 300 can be stacked together and laminated using heat and pressure. For example, all of the layers can be simultaneously laminated into a stack. Alternatively, the layers can be built upon a metal core layer 335 one at a time, or incrementally built with one or two additional layers added in each lamination step. During lamination, dielectric layers 361, 362, 363, 364, 365 and 366 melt and flow to provide a monolithic bulk dielectric material 360.

Through vias can be formed following lamination of interconnect substrate 300. In particular, vias can be formed by drilling or laser ablation processes as described, for example, in U.S. Pat. No. 6,021,564. Following lamination, solder masks 310 and 315 are added to interconnect substrate 300. Solder masks 310 and 315 are then patterned to define contact pads 357, 390, for receipt of solder balls from a chip 355 and PWB (not shown), respectively.

FIG. 4 is a schematic representation of a portion of one possible interconnect substrate in combination with which the invention herein described may be used. FIG. 4 shows a 5-layer interconnect substrate 400 made by laminating alternating series of metal layers (420, 425, 430 (core), 435, 440) and dielectric layers (461, 462, 463, 464). The metal and dielectric layers shown in FIG. 4 are disposed symmetrically about core metal layer 430. That is, each dielectric or metal layer formed on one side of core layer 430 has a corresponding layer of the same material formed on the opposite side of the core layer.

As further shown in FIG. 4, a first via 480 extends through dielectric layer 461 from metal layer 420 and terminates at metal layer 425. A second via 475 begins at metal layer 425 and extends through dielectric layers 462, 463 and terminates at metal layer 435. A third via 470 extends through dielectric layer 464 from metal layer 435 terminates at metal layer 440. Each via 470, 475, 480 is plated with conductive material using any of the deposition techniques that are well known in the microelectronic fabrication art. Alternatively, each via 470, 475, 480 is filled with an electrically conductive material to define a conductive path. One skilled in the art will recognize that any combination of vias can be used to provide electrical connections between the bond pads 457 on the die attach surface 404 and the bond pads 490 on the BGA attach surface 402, including blind vias, buried vias and through vias.

Solder masks 410, 415 can be applied to chip attach surface 404 and BGA attach surface 402. Each solder mask 410, 415 exposes a contact or bond pad adjacent to each via 470, 480. For example, solder mask 410 exposes contact pads 457, whereas solder mask 415 exposes contact pads 490. Solder balls 455 associated with the chip can be aligned over contact pads, 457, heated, and reflowed to form an electrical and mechanical bond with the contact pads. Likewise, solder balls (not shown) associated with the board can be aligned over contact pads, 490, heated, and reflowed to form a electrical and mechanical bond between the contact pads and the PWB.

The dielectric layers 461, 462, 463, 464 may be formed from laminates of high-temperature organic dielectric substrate materials, such as polyimides and polyimide laminates, epoxy resins, liquid crystal polymers, organic materials, or dielectric materials comprised at least in part of polytetrafluoroethylene, with or without a filler. In one embodiment, dielectric layers 461, 462, 463, 464 are made of an organic material such as polytetrafluoroethylene (PTFE), and more particularly, an expanded PTFE or “ePTFE” which is impregnated with cyanate ester and epoxy. The PTFE material may be, in particular, an expanded polytetrafluoroethylene matrix containing a mixed cyanate ester-epoxy adhesive and inorganic filler.

Metal layers 420, 425, 430, 435, 440 may be formed from copper. Other suitable metal materials can also be used such as aluminum, gold, or silver. In this example, metal layers 420, 425, 435, 440 may each have a thickness in the range of approximately 5 to 14 microns. In one example, the thickness of each metal layer 420, 425, 435, 440 is approximately 12 microns. The core metal layer 430 may have a thickness in the range of approximately 5 to 50 microns. Dielectric layers 461, 462, 463, 464 may each have a thickness in the range of approximately 20 to 70 microns. In one example, the thickness of each dielectric 461, 462, 463, 464 layer is approximately 36 microns.

The various layers of interconnect substrate 400 can be stacked together and laminated using heat and pressure. For example, all of the layers can be simultaneously laminated with another in a stack. Alternatively, the layers can be built upon a metal core layer 430 one at a time, or incrementally built with one or two additional layers added in each lamination step. During lamination, dielectric layers 461, 462, 463, 464 melt and flow to provide a monolithic bulk dielectric material 460.

Through vias can be formed following lamination of interconnect substrate 400. In particular, vias can be formed by drilling or laser ablation processes as described, for example, in U.S. Pat. No. 6,021,564. Following lamination, solder masks 410 and 415 are added to interconnect substrate 400. Solder masks 410 and 415 are then patterned to define contact pads 457, 490 for receipt of solder balls from a chip 455 and PWB (not shown), respectively.

Interconnect substrates 300 or 400 can accept a “flip-chip” integrated circuit. Flip-chip mounting entails placing solder balls on a die (i.e., chip), flipping the chip over, aligning the chip with the contact pads on a substrate, such as interconnect substrate 300 or 400, and reflowing the solder balls in a furnace to establish bonding between the chip and the substrate. In this manner, the contact pads are distributed over the entire chip surface rather than being confined to the periphery as in wire bonding and tape-automated bonding (TAB) techniques. As a result, the maximum number of I/O and power/ground terminals available can be increased, and signal and power/ground interconnections can be more efficiently routed on the chips.

It should be recognized by those skilled in the art that interconnect substrates of the types reflected in the above embodiments may contain additional layers including embedded capacitor layers, metal layers, dielectric layers and the like. It is also possible to make interconnect substrates having fewer dielectric and metal layers depending on the requirements of the final interconnect module.

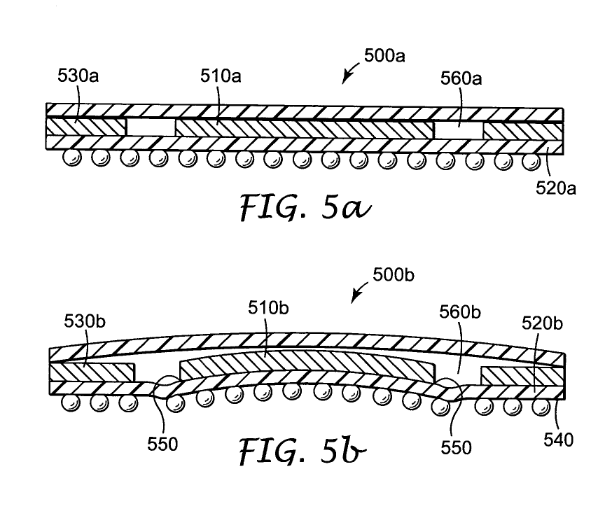

Die corner cracks form primarily from the mechanical constraint imposed by a stiffener ring and/or lid. As shown in FIG. 5a, at elevated temperature, e.g. close to that used to gel and cure the various adhesive materials during the assembly process, the assembled module 500a is in a mostly stress-free state. However, as shown in FIG. 5b, when cooled to a lower temperature, the mismatch in CTE between the die 510b and other components of the assembled module 500b, particularly between the die and the interconnect substrate 520b, causes the package to attempt to assume a concave downward shape. However, the stiffener ring 530 prevents this from happening, instead holding the region of the substrate that it covers in a flat shape. The transition between the concave downward profile of the region under the die and the largely flat profile under the stiffener ring occurs in the gap between the die and stiffener ring as shown schematically in FIG. 5b. This change in shape over a short distance results in tensile bending strains developing on the BGA side 540 of the substrate. This is particularly true in the regions near the die corners 550 as there is a simultaneous curvature in both the x and y directions.

The more abrupt the change in shape, the higher the strain that will exist at the die corners and in the gap 560 between the die 510 and stiffener ring 530. Conversely, if the change in shape can be made to occur more gradually, the strain will be reduced. Therefore, one action that can be taken to mitigate the problem is to increase the spacing between the die and stiffener ring. The larger the space between the die and the stiffener ring, the lower the critical strain. A lower critical strain will allow the use of a smaller solid plane area.

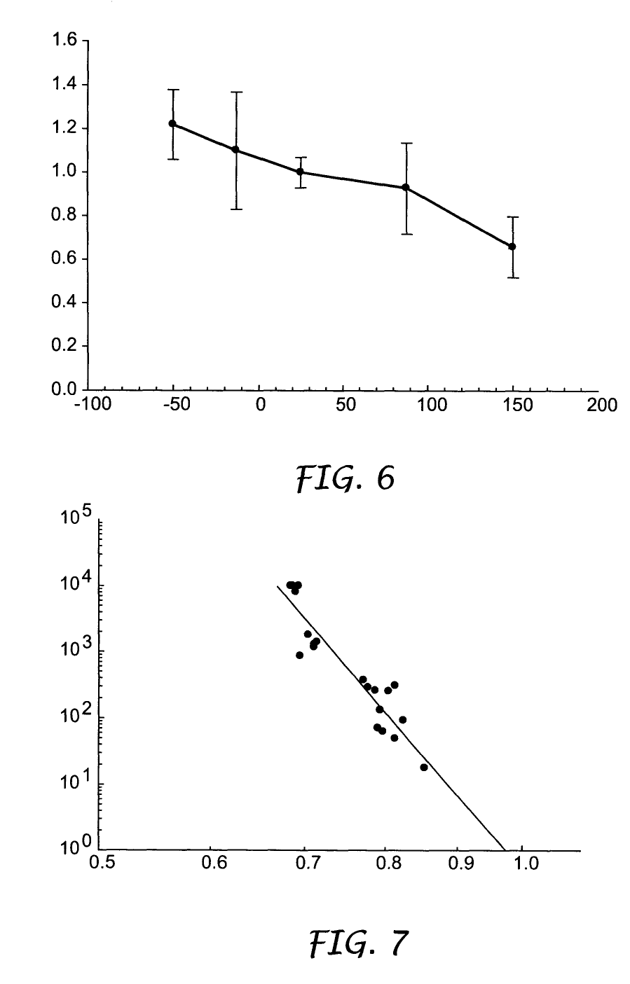

For example, in the case of a substrate using expanded polytetrafluoroethylene dielectric material, available under the tradename MICROLAM from W.L. Gore and Assoc., Newark, Del., the mechanical properties of the MICROLAM dielectric must be considered in order to calculate this critical strain. First, the flexural breaking strain of MICROLAM has been measured as being 0.47%±0.15%. Second, the fracture toughness of MICROLAM has been measured and is shown as a function of temperature in FIG. 6. Lastly, the fatigue properties of the material have been measured and are shown in FIG. 7.

The data shows a power law dependence on the stress intensity:

$${N}_{f} = 0.5 {( \frac{{K}_{I}}{{K}_{I c}} )}^{- 24.46}$$

where N_{f} is the cycles to failure, K_{I} is the stress intensity factor, and K_{Ic} is the critical stress intensity or fracture toughness.

A conservative cycles-to-failure requirement for the electronics industry is 10000 cycles. From FIG. 7 this leads to a K_{I}/K_{Ic} ratio of approximately 0.7. Realizing that K_{I}∝σ₁∝ε₁ (for an isotropic, homogeneous material), the local strain must be maintained below 0.7 of the fracture strain or 0.33%.

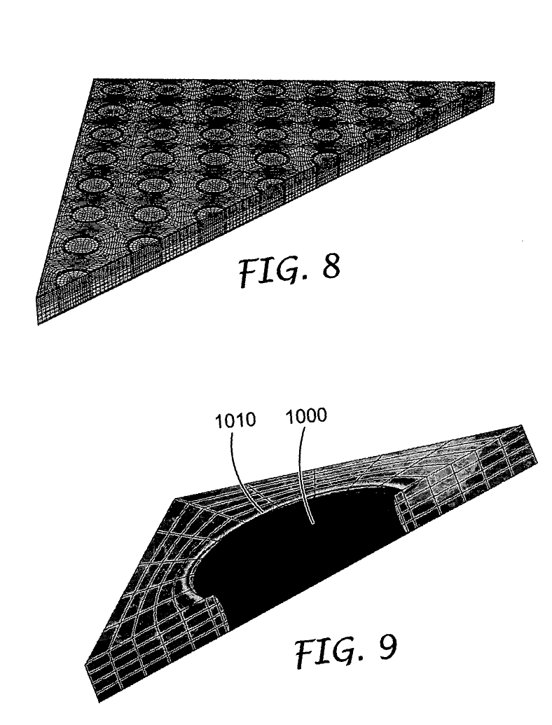

FIG. 8 shows a detailed finite element model of a 9 mm×9 mm section of a seven metal layer package substrate. FIG. 9 shows the stress in the BGA side dielectric around a single BGA pad when the model of FIG. 8 was subjected to a uniform biaxial strain. A region of high strain exists immediately around the edge of the BGA pad 1000 as indicated by the white ring 1010. FIG. 10 shows the degree of localization of this high stress region. The region of high stress or strain is only approximately 75 μm wide and approximately 25 μm deep. The magnitude of the high stress or strain in this region is approximately twice the nominal stress or strain.

Knowing that cracks in the MICROLAM dielectric material in the die corner regions can be eliminated by maintaining nominal strain below 0.17%, possible solutions to the die corner cracking issue could be formulated. However, if the strain concentrations caused by the BGA pads or other geometric discontinuities were not present, the nominal stress could be allowed to be as high as 0.34% without forming cracks during thermal cycling.

According to the present invention, an area without geometric discontinuities is provided on the BGA attach surface in the region near the die corners. This may be accomplished by an embodiment in which the BGA attach surface region near one or more die corners consists of a solid plane of dielectric material, optionally covered with a solid layer of soldermask or coverlay material.

In another embodiment, the region near one or more die corners may consist of a solid plane of metal, optionally covered with a solid layer of soldermask or coverlay material.

In yet another embodiment, the region near one or more die corners may consist of a solid plane of metal, covered with a soldermask material, said soldermask having openings forming defined BGA pads. This embodiment provides the benefit of a solid plane area near a die corner while still allowing the area to be functional. Use of a metal plane rather than a dielectric plane is more desirable because of the high strength and ductility of most metals compared to most dielectric materials. The use of a metal plane with openings in the covering soldermask is desirable because, first, it allows use of some of the pad locations to form mechanical interconnects with the PWVB (for higher rigidity and support). Second, it allows those pad locations joined to the metal plane to be used to make an electrical connection to power or ground, thus avoiding the complete loss of valuable I/O connections. This in turn helps avoid expanding the dimensions of the package and resulting cost increases to both the manufacturer and user.

The lateral dimensions of the solid planes depends on factors such as the die size and thickness, substrate thickness, dielectric material properties, stiffener thickness and material, die-stiffener gap, lid thickness and material, and underfill properties (such as modulus, glass transition temperature, gel temperature, etc.) and the like.

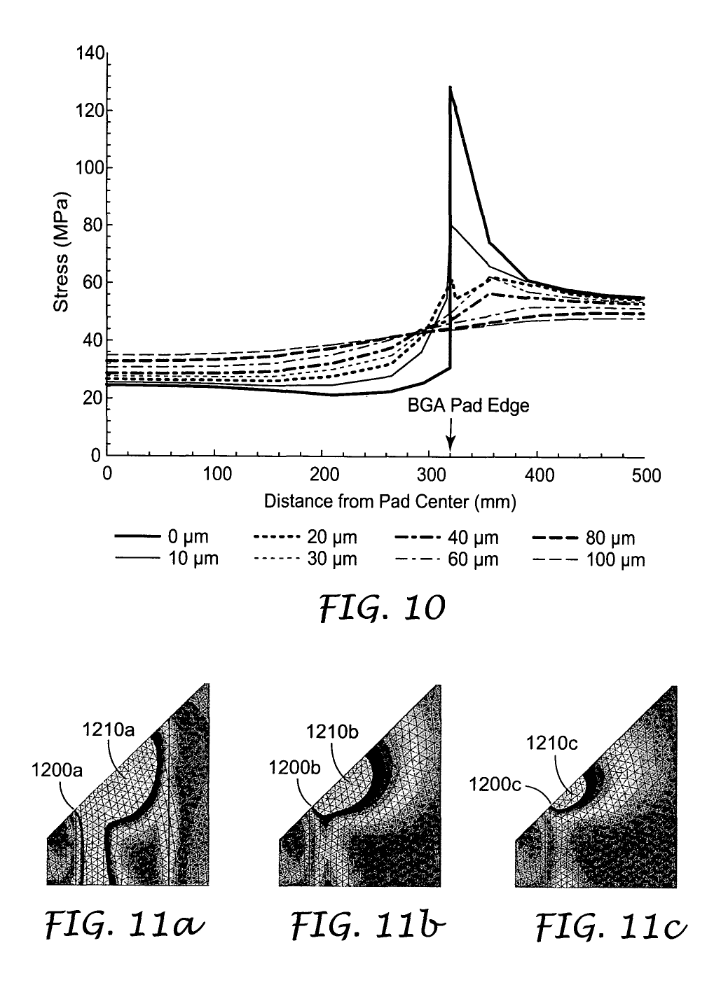

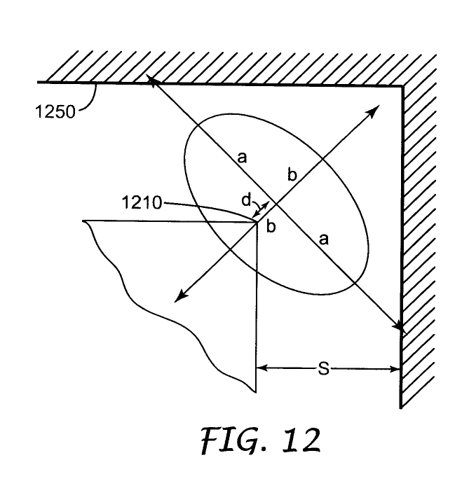

Finite element models can be used to determine the appropriate size of the solid planes. FIG. 11 shows results from a model of a 40 mm square package with an 18.5 mm die and a 1.0 mm thick lid with several die-stiffener spacings (3 mm (FIG. 11a), 5 mm (FIG. 11b), and 7 mm (FIG. 11c)). A high strain region 1210 exists near the die corner 1200 where the strain is greater than the critical strain at which cracking will occur. An aspect of the invention herein disclosed allows the means to adjust the area of, and locate the position of, a solid plane where a geometric discontinuity would cause a crack to form during assembly, testing, or use of the final interconnect module. The edges of the solid plane preferably extend beyond the high strain region because the edges of the solid plane themselves are discontinuities that could initiate cracks if the critical strain is exceeded. For the purposes of this particular analysis, the critical strain level was set at a value equal to ⅓ of the 95% confidence interval on the experimental fracture strain for MICROLAM dielectric material or 0.11%.

As can be seen from FIGS. 11a to 11c, the area of the plane needed shrinks considerably as the die-stiffener gap is increased. An aspect of the invention described herein allows for the creation of a general design rule, which will simplify design of these IC packages by reducing the need for a complete detailed finite element model of every design.

In at least one embodiment, a metal plane is located on the BGA pad layer at one or more die corner (e.g., metal layer 350 in FIG. 3 or e.g., metal layer 440 in FIG. 4). Each metal plane encompasses all BGA pads that contact an elliptical region whose size and shape are defined by the following equation:

$${( \frac{x}{a} )}^{2} + {( \frac{y}{b} )}^{2} = 1$$

where x and y are in millimeters. Elements a and b are measurements as shown in FIG. 12. Also as shown in FIG. 12, the center of this ellipse is located a distance “d” outward from the die corner along the diagonal with the minor axis of the ellipse coincident with a line bisecting the die corner 1210 and extending to the starting edge of die stiffener ring 1250. Die stiffener ring 1250 may be made of metal or dielectric. Some parameters will be different depending on whether the solid plane material is a metal or dielectric. The high strain region also might be different depending on the material comprising the solid plane. FIG. 12 shows the elliptical region for one die corner region. Outside of this elliptical region, the mean stress level on the BGA side of the package does not reach a level sufficient to initiate or propagate cracks under normal thermal cycling conditions.

The values of a, b, and d vary with the spacing between the die and the stiffener ring (S on FIG. 12) as shown in the following table.

| Die-Stiffener | | | |
|---|---|---|---|
| Spacing | a | b | d |
| (S) | (mm) | (mm) | (mm) |
| 3.0 mm | 2.79 | 1.07 | 0.62 |
| 4.0 mm | 2.50 | 0.95 | 0.57 |
| 5.0 mm | 2.25 | 0.85 | 0.48 |
| 6.0 mm | 1.85 | 0.73 | 0.38 |
| 7.0 mm and | 1.58 | 0.63 | 0.38 |
| greater | | | |

In practical application, if the die corner is coincident with a BGA pad location, the solid plane should extend a distance equal to at least two BGA rows beyond the die edge, and one row under the die.

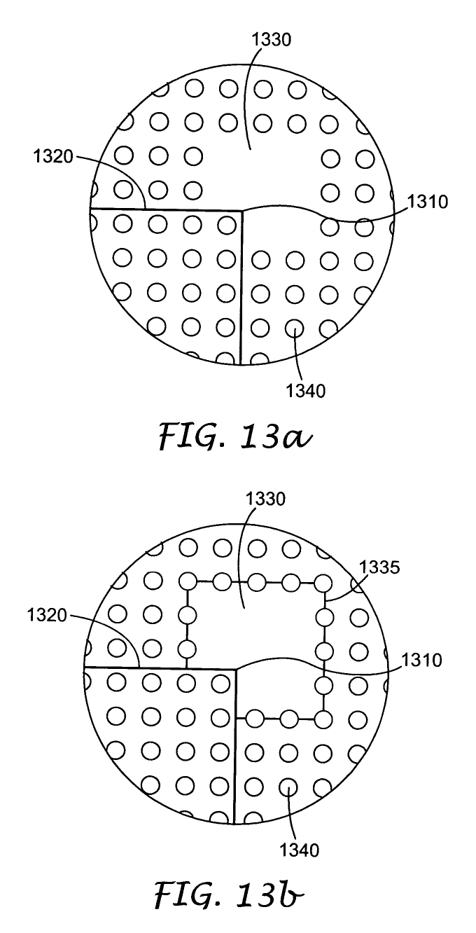

FIG. 13a illustrates an embodiment of a solid plane covering the BGA pad layer region near a die corner 1310 formed at the intersection of die edges 1320. In this embodiment, the solid plane is formed by providing an unpatterned area 1330 (i.e., having no solder ball pads 1340) of the BGA pad layer at and around a die corner.

FIG. 13b illustrates another embodiment similar to that illustrated in FIG. 13a. However, in FIG. 13b unpatterned area 1330 is physically isolated from the remainder of the BGA pad layer by channel 1335. Channel 1335 may be formed by removing material from the BGA pad layer, or by masking the channel when the material forming BGA pad layer is deposited.

A solid plane may also be formed by adding a layer of unpatterned material on the BGA pad layer (whether the BGA pad layer is patterned or not) at and around one or more die corner. The added layer may extend under the die or abut the die corner and adjacent portions of the die edges. The layer may be a metal or a dielectric material.

### EXAMPLES

Two packages, one that incorporated the metal plane described above (Package A) and one that did not (Package B), were designed, fabricated and assembled. Except for the crack reducing features, they were identical. Both used a 10.6-mm×12.0-mm die and a 7-metal layer substrate. The internal circuitry of both was identical, but the BGA side metal layer layout of Package A used metal planes at the die corners designed as described above, while Package B did not. In addition, Package A used a stiffener with a larger opening giving a die-stiffener gap of 6.6 mm×6.9 mm and a 0.5 mm thick lid. Package B used a stiffener with an opening that provided a 2.8 mm×3.5 mm die-stiffener gap and a 1.0 mm thick lid. Thus, Package A used four metal plane of this invention, while Package B used none of them.

Samples of both packages were assembled with die using the same assembly recipe. After assembly the samples were subjected to thermal cycling from 125° C. to −55° C. for 1500 cycles. After thermal cycling, Package A showed no cracks in the BGA side dielectric of 35 samples examined. Package B, on the other hand showed visible die corner cracks in 9 out of 35 samples.

While various embodiments of the invention have been herein described, these and other embodiments are within the scope of the following claims. For example, the embodiments of the invention described herein may be used in combination with any of the additional structure or processes described in the following U.S. patents: U.S. Pat. No. 5,888,630, U.S. Pat. No. 6,018,196, U.S. Pat. No. 5,983,974, U.S. Pat. No. 5,836,063, U.S. Pat. No. 5,731,047, U.S. Pat. No. 5,841,075, U.S. Pat. No. 5,868,950, U.S. Pat. No. 5,888,631, U.S. Pat. No. 5,900,312, U.S. Pat. No. 6,011,697, U.S. Pat. No. 6,021,564, U.S. Pat. No. 6,103,992, U.S. Pat. No. 6,127,250, U.S. Pat. No. 6,143,401, U.S. Pat. No. 6,183,592, U.S. Pat. No. 6,203,891, and U.S. Pat. No. 6,248,959.

1. A laminated flip-chip interconnect package comprising a substrate having a chip attach surface and a board attach surface that define contact pads for attachment to corresponding pads on the chip and board, wherein the substrate board attach surface comprises at least one solid plane covering the chip attach surface region near at least one chip corner, said solid plane comprising a dielectric material.

2. A laminated flip-chip interconnect package according to claim 1 wherein said dielectric material is covered with a layer of material selected from a soldermask and a coverlay material.

3. A laminated flip-chip interconnect package according to claim 2 wherein said layer of material is selected from the group consisting of polyimide, polytetrafluoroethylene, and expanded polytetrafluorethylene impregnated with cyanate ester and epoxy.

4. A laminated flip-chip interconnect package comprising a substrate having a chip attach surface and a board attach surface that define contact pads for attachment to corresponding pads on the chip and board, wherein the substrate board surface comprises at least one solid plane covering the chip attach surface region near the chip corners, said solid plane comprising a metal.

5. A laminated flip-chip interconnect package according to claim 4 wherein said metal is selected from the group consisting of copper, silver, gold and aluminum.

6. A laminated flip-chip interconnect package according to claim 4 wherein said metal is covered with a layer of material selected from a soldermask and a coverlay material.

7. A laminated flip-chip interconnect package according to claim 6 wherein said layer of material is selected from the group consisting of polyimide, polytetrafluoroethylene, and expanded polytetrafluorethylene impregnated with cyanate ester and epoxy.

8. A laminate flip-chip interconnect package according to claim 4 wherein said soldermask has a plurality of openings defining ball grid array pads.
